(19) United States
(12) Patent Application Publication
(10) Pub. No.: US 2011/0012188 A1
(43) Pub. Date: Jan. 20, 2011

(54) SEMICONDUCTOR MEMORY DEVICE

(75) Inventors: Masaru KITO, Kanagawa-ken (JP); Ryota Katsumata, Kanagawa-ken (JP); Yoshiaki Fukuzumi, Kanagawa-ken (JP); Masaru Kidoh, Tokyo (JP); Hiroyasu Tanaka, Kanagawa-ken (JP); Yosuke Komori, Mie-ken (JP); Megumi Ishiduki, Kanagawa-ken (JP); Tomoko Fujiwara, Kanagawa-ken (JP); Hideaki Aochi, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/728,658

(22) Filed: Mar. 22, 2010

(30) Foreign Application Priority Data
Jul. 14, 2009 (JP) 2009-165741

(51) Int. Cl. H01L 27/105

(52) U.S. Cl. 257/324; 257/E27.081

(57) ABSTRACT

A semiconductor memory device includes: a stacked body formed of a plurality of inter-layer insulating films and a plurality of electrode films alternately stacked and having a through-hole formed in the stacking direction; an electrode-side insulating film of a film thickness of 4 nm or more provided on an inner surface of the through-hole; a charge storage film provided on the electrode-side insulating film; a semiconductor-side insulating film of a film thickness of 4 nm or more provided on the charge storage film; and a semiconductor pillar buried in the through-hole.

### CROSS-REFERENCE TO RELATED APPLICATIONS

This application is based upon and claims the benefit of priority from the prior Japanese Patent Application No. 2009-165741, filed on Jul. 14, 2009; the entire contents of which are incorporated herein by reference.

### BACKGROUND

1. Field

Embodiments of the invention relate generally to a semiconductor memory device.

2. Background Art

Conventionally, OTP (One Time Programmable) memory devices of low costs and large capacities have been practically used. Generally, as the memory cells of the OTP memory devices fuse elements, which semi-permanently store binary data of “0” and “1”, are used. The fuse elements illustratively include antifuses which are initially insulating but are broken by the application of write voltages and become conductive.

Recently, techniques of three-dimensionally laying out the memory cells are proposed to improve the integration of the memory cells to thereby decrease the cost per 1 bit. For example, Reference “Evaluation of SiO₂ Antifuse in a 3D-OTP Memory” Feng Li, et al., IEEE TRANSACTIONS ON DEVICE AND MATERIALS RELIABILITY, VOL. 4, NO. 3, SEPTEMBER 2004, p. 416-421 discloses the technique alternately stacking bit lines with word lines and connecting memory plugs formed of fuse elements and diodes between the bit lines and the word lines.

However, the memory plugs and the word lines must be simply repeated to manufacture the 3D stacked-type OTP memory device described above, pattering process of the bit lines. Accordingly, the increase of the number of stacked layers increases the number of lithography processes, which increases the manufacturing cost. Furthermore, the patterning process of them is of critical dimensions, which causes much load to the processing. Accordingly, even when the number of stacked layers is increased, the reduction of the material cost by the decrease of the chip area per 1 bit is compensated by the increase of the manufacturing cost. Resultantly, it is difficult to decrease the cost per 1 bit.

### SUMMARY

According to an aspect of the invention, there is provided a semiconductor memory device including: a stacked body formed of a plurality of inter-layer insulating films and a plurality of electrode films alternately stacked and having a through-hole formed in the stacking direction; an electrode-side insulating film of a film thickness of 4 nm or more provided on an inner surface of the through-hole; a charge storage film provided on the electrode-side insulating film; a semiconductor-side insulating film of a film thickness of 4 nm or more provided on the charge storage film; and a semiconductor pillar buried in the through-hole.

According to an aspect of the invention, there is provided a semiconductor memory device including: a semiconductor substrate; a semiconductor-side insulating film of a film thickness of 4 nm or more provided on the semiconductor substrate; a charge storage film provided on the semiconductor-side insulating film; an electrode-side insulating film of a film thickness of 4 nm or more provided on the charge storage film; and an electrode provided on the electrode-side insulating film. The semiconductor-side insulating film and the electrode-side insulating film being formed of identical material,

### BRIEF DESCRIPTION OF THE DRAWINGS

FIG. 1 is a perspective view illustrating a one time programmable semiconductor memory device according to a first embodiment of the invention;

FIG. 2 is a cross-sectional view illustrating the one time programmable semiconductor memory device according to the first embodiment;

FIG. 3 is a partial cross-sectional view illustrating the interior of a through-hole of the one time programmable semiconductor memory device according to the first embodiment;

FIGS. 4 to 6 are cross-sectional views of processes illustrating a method for manufacturing the one time programmable semiconductor memory device according to the first embodiment;

FIG. 7 is a partial cross-sectional view illustrating the interior of a through-hole of a one time programmable semiconductor memory device according to a first variation of the first embodiment;

FIG. 8 is a partial cross-sectional view illustrating the interior of a through-hole of a one time programmable semiconductor memory device according to a second variation of the first embodiment;

FIG. 9 is a perspective view illustrating a one time programmable semiconductor memory device according to a second embodiment of the invention;

FIG. 10 is a plan view illustrating a one time programmable semiconductor memory device according to a third embodiment of the invention;

FIG. 11 is a cross-sectional view taken along A-A′ line shown in FIG. 10;

FIG. 12 is a cross-sectional view illustrating a one time programmable semiconductor memory device according to a first variation of the third embodiment; and

FIG. 13 is a cross-sectional view illustrating a one time programmable semiconductor memory device according to a second variation of the third embodiment.

### DETAILED DESCRIPTION

Embodiments of this invention will be described with reference to the drawings.

First, a first embodiment of this invention will be described.

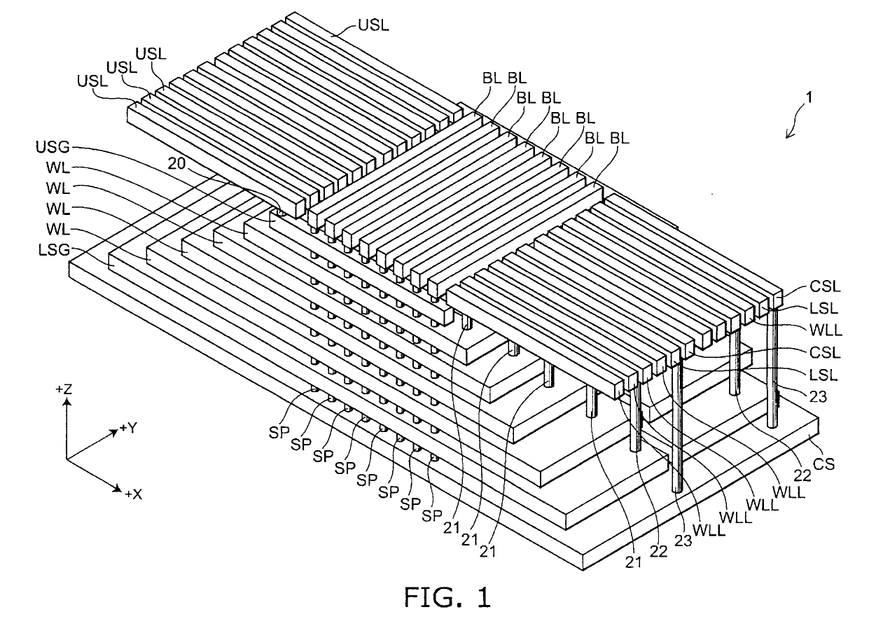

FIG. 1 is a perspective view exemplifying the one time programmable semiconductor memory device according to this embodiment.

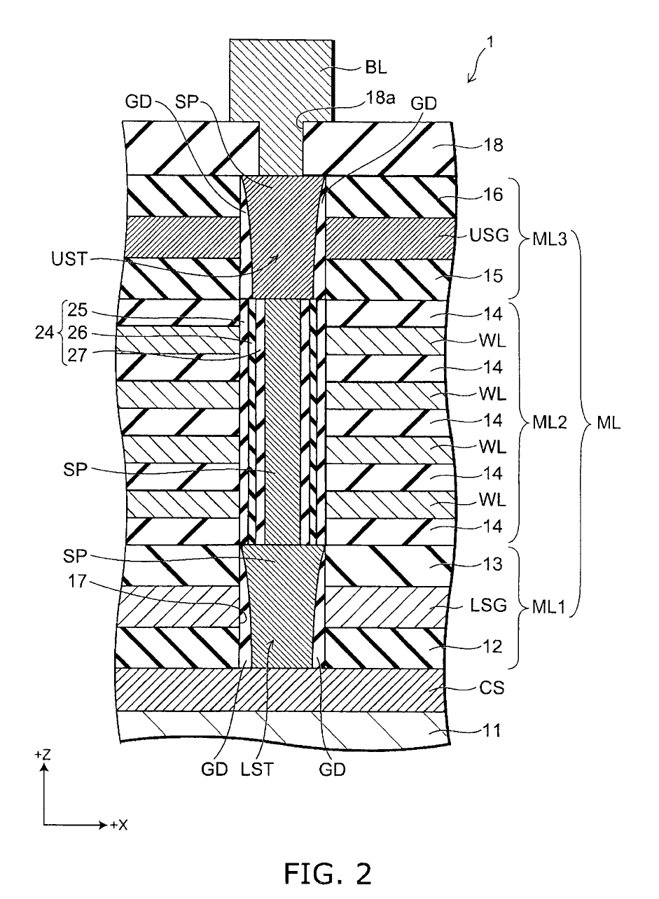

FIG. 2 is a cross-sectional view exemplifying the one time programmable semiconductor memory device according to this embodiment.

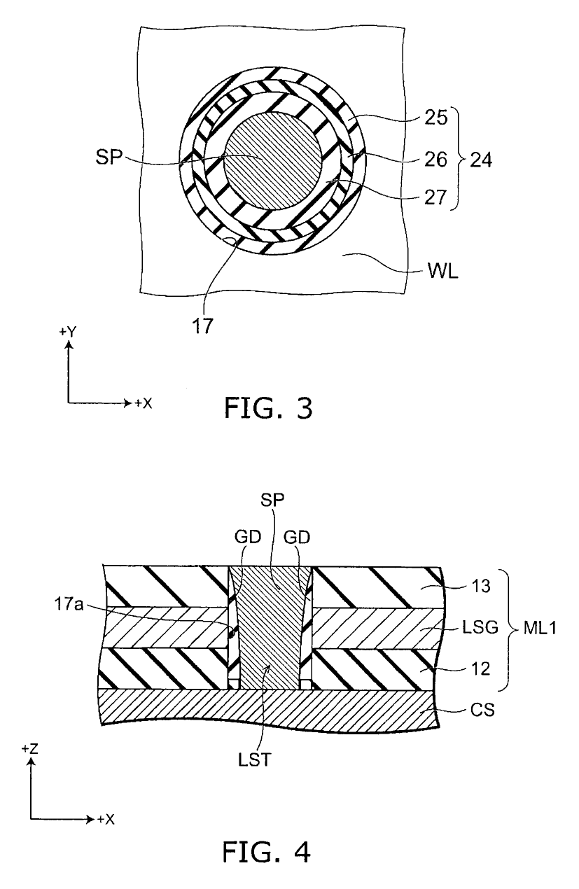

FIG. 3 is a partial cross-sectional view exemplifying the inside of the through-hole of the one time programmable semiconductor memory device according to this embodiment.

In FIG. 1, to make the drawing illustrative, only the conductive portions are illustrated, and the insulating portions are not illustrated.

As illustrated in FIGS. 1 and 2, the one time programmable semiconductor memory device according to this embodiment (hereinafter called singly “the device 1”) is a three dimensional stacked-type memory device. As described alter, cell transistors are arranged in a three-dimensional matrix in the device 1. Each cell transistor includes a charge storage film 26 and stores charges in this charge storage film 26 to store data. Thus, each cell transistor functions as a memory cell.

In the one time programmable semiconductor memory device 1 according to this embodiment, a silicon substrate 11 of, e.g., single crystal silicon is provided. In the silicon substrate 11, a memory array region where memory cells are formed and a peripheral region where peripheral circuits for driving the memory cells are configured.

First, the configuration of the memory array region will be described.

In the memory array region, an impurity is implanted in an upper layer portion of the silicon substrate 11 to form a rectangular cell source CS. On the area immediately on the cell source CS of the silicon substrate 11, an insulating film 12 of, e.g., silicon oxide (SiO₂) is provided, and thereon, a lower selection gate LSG of, e.g., non-crystalline silicon is provided, and thereon, an insulating film 13 of, e.g., silicon oxide is provided. The insulating film 12, the lower selection gate LSG and the insulating film 13 form a stacked body ML1.

Above the stacked body ML1, a plurality of inter-layer insulating films 14 of, e.g., silicon oxide and a plurality of electrode films WL of, e.g., non-crystalline silicon are alternately stacked to form a stacked body ML2. The electrode films WL function as word lines. The inter-layer insulating films 14 are provided on and below the electrode films WL and between the electrode films WL.

On the stacked body ML2, an insulating film 15 of, e.g., silicon oxide is provided. Upper selection gates USG are provided thereon, and an insulating film 16 of, e.g., silicon oxide is provided thereon. The insulating film 15, the upper selection gates USG and the insulating film 16 form a stacked body ML3. As described above, the stacked body ML1, the stacked body ML2 and the stacked body ML3 are sequentially stacked on the silicon substrate 11. A plurality of sets of the stacked body ML1, the stacked body ML2 and the stacked body ML3 (hereinafter generally called also “stacked body ML”) are provided in the Y direction.

In this specification, for the convenience of the description, the XYZ orthogonal coordinate system is used. In this coordinate system, two directions which are parallel with the upper surface of the silicon substrate 11 and are mutually orthogonal to each other are the X direction and the Y direction, and the direction orthogonal to both the X direction and the Y direction, i.e., the direction of the stack of the inter-layer insulating films 14 and the electrode films W is Z direction.

The higher stacked electrode films WL have shorter in the X direction and the Y direction, and, as viewed from above (in the +Z direction), the respective electrode films WL are positioned inner side of the lower positioned electrode films WL and inner side of the lower selection gate LSG and the cell source CS. The upper selection gates USG are positioned inner side of the uppermost electrode film WL. Thus, the end of the stacked body ML is stepped. Inter-layer insulating films (not illustrated) are provided in the regions in the ±X direction and the ±Y direction as viewed from the stacked body ML.

The upper electrode gates USG are formed of one sheet of conductive film of, e.g., non-crystalline silicon divided in the Y direction and line-shaped conductive members extended in the X direction. The electrode film WL and the lower selection gate LSG are not divided in each stacked body ML and are respectively one sheet of conductive film parallel with the XY plane. The cell source CS is not divided either and forms a conductive region of one sheet of layer parallel with the XY plane, connecting the areas immediately below the plural stacked bodies ML.

In the stacked body ML, a plurality of through-holes are formed, extended in the stacking direction (X direction). The respective through-holes are passed entirely through the stacked body ML. That is, the through-hole 17 is respectively passed through the insulating film 12, the lower selection gate LSG and the insulating film 15 forming the stacked body ML1, the inter-layer insulating film 14 and the electrode film WL forming the stacked body ML2 and the insulating film 15, the upper selection gate USG and the insulating film 16 forming the stacked body ML2 at the same position as viewed in the X direction. The through-holes 17 are arranged in a matrix in, e.g., the X direction and the Y direction, and the cycle of the arrangement is constant in the respective X direction and Y direction.

Silicon pillars SP are buried in the respective through-holes 17. The silicon pillars SP are formed of a conductor doped with an impurity, e.g., polycrystalline silicon or non-crystalline silicon. The silicon pillars SP are in the shape of a cylinder extended in the Z direction. The silicon pillars SP are provided over the entire length of the stacked body ML in the stacking direction and have the lower ends connected to the cell source CS.

An insulating film 18 is provided on the stacked body ML3. On the insulating film 18, a plurality of bit lines BL are provided, extended in the Y direction. The bit lines BL are formed of a metal, e.g., tungsten (W), aluminum (Al) or copper (Cu). The respective bit lines are arranged along the areas very above the silicon pillars SP of the respective columns of the silicon pillars SP arranged in the Y direction and are connected to the upper ends of the silicon pillars SP via via-holes 18a formed in the insulating film 18. Thus, the silicon pillars SP of the respective columns of the silicon pillars arranged in the Y direction are connected to the different bit lines BL. That is, the respective silicon pillars SP are connected between the bit lines BL and the cell source CS.

Furthermore, on the -X direction side of the area where the bit lines BL are arranged, a plurality of upper selection gate lines USL extended in the X direction are provided. The upper selection gate lines USL are formed of a metal, e.g., tungsten, aluminum or copper. The number of the upper selection gate lines USL is the same as that of the upper selection gates USG, and the respective upper selection gate lines USL are connected to the respective upper selection gates USG respective vias 20. Furthermore, on the +X direction side of the area where the bit lines BL are arranged, for each stacked body ML, a plurality of word lines WLL extended in the X direction, one lower selection gate line LSL extended in the X direction, and one cell source line CSL extended in the X direction are provided. The word lines WLL, the lower selection gate line LSL and the cell source line CSL are formed of a metal, e., g, tungsten, aluminum or copper. The number of the word lines WLL associated with one stacked body ML is the same of the electrode films WL, which are word lines, and the respective word lines WLL are connected to the respective word films WL via vias 21. The lower selection gate line LSL is connected to the lower selection gate LSG via a via 22, and the cell source line CSL is connected to the cell source CS via a contact 23. The vias 21, 22 and the contact 23 are formed in regions immediately above the electrode films WL being connected thereto and offset in the +X direction as viewed from an upper electrode film WL with respect to the electrode films WL.

The bit lines BL, the upper selection gate lines US, the word lines WLL, the lower selection gate line SLS and the cell source lines CLS have the same position in the Z direction, the same thickness and material and are formed by, e.g., patterning one sheet of metal film. The respective lines are insulated from each other by inter-layer insulating films (not illustrated).

As illustrated in FIGS. 2 and 3, an ONO film (Oxide Nitride Oxide film) 24 is provided in the cylindrical space between the portion (hereinafter called also “the middle portion of the silicon pillar”) of each silicon pillar SP positioned in the stacked body ML2 and the side surface of the through hole 17. The ONO film 24 is formed of an electrode-side insulating film 25, a charge storage film 26 and a semiconductor-side insulating film 27 stacked in the stated order from the outside, i.e., from the side of the electrode films WL. The electrode-side insulating film 25 is in contact with the inter-layer insulating film 14 and the electrode film WL, and the semiconductor-side insulating film 27 is in contact with the silicon pillar SP.

In this embodiment, the electrode-side insulating film 25 and the semiconductor-side insulating film 27 are formed of the same material, e.g., silicon oxide (SiO₂). On the other hand, the charge storage film 26 is formed of a material being able to retain charges, e.g., a material having trap sites of electrons and is formed of, e.g., silicon nitride (SIN). The electrode-side insulating film 25 and the semiconductor-side insulating film 27 have film thicknesses which prevent direct tunneling, specifically, 4 nm (nanometers) or more, respectively. Furthermore, the semiconductor-side insulating film 27 has a film thickness which generates FN tunneling when a prescribed voltage in the range of the drive voltage of the device 1 is applied. Furthermore, in this embodiment, the film thickness of the electrode-side insulating film 25 is smaller than the film thickness of the semiconductor-side insulating film 27.

Thus, the middle portion of the silicon pillar SP functions as a channel, and the electrode films WL function as control gates, whereby MONOS cell transistors are formed at the intersections between the silicon pillar SP and the electrode films WL. Whether or not a charge is stored in the charge storage layer 26 is used as information, whereby this cell transistor functions as a memory cell.

Resultantly, around one silicon pillar SP, the same number of memory cells as that of the electrodes films WL are arranged in one column, and one memory string is formed. In the device 1, a plurality of the silicon pillars SP are arranged in a matrix in the X direction and the Y direction, whereby a plurality of memory cells are three-dimensionally arranged in the X direction, the Y direction and the Z direction.

On the other hand, a gate insulating film GD is provided in the cylindrical space between the portion (hereinafter called also “the lower portion of the silicon pillar”) of the silicon pillar SP positioned inside the stacked body ML1 and the side surface of the through-hole 17. Thus, a lower selection transistor LST having the lower portion of the silicon pillar SP as the channel and the lower selection gate LSG as the gate is formed in the stacked body ML1.

Furthermore, a gate insulating film GD is provided also in the cylindrical space between the portion (hereinafter called also “the upper portion of the silicon pillar”) positioned inside the stacked body L3 of the silicon pillar SP and the side surface of the through-hole 17. Thus, an upper selection transistor UST having the upper portion of the silicon pillar SP as the channel and the upper selection gate USG as the gate is formed in the stacked body ML3. The lower selection transistor LST and the upper selection transistor UST do not function as memory cells and operate to select the silicon pillar SR

Next, the configuration of the circuit region will be described.

In the circuit region (not illustrated) of the device 1, there are provided a bit line driver circuit which applies potentials to the upper ends of the silicon pillars SP via the bit lines BL, a cell source driver circuit which applies potentials to the lower ends of the silicon pillars SP via the cell source lines CLS, the contact 23 and the cell source CS, an upper selection gate driver circuit which applies potentials to the upper selection gates USG via the upper selection gate lines USL and the vias 20, a lower selection gate driver circuit which applies potentials to the lower selection gates LSG via the lower selection gate lines LSL and the vias 22, and a word line driver circuit which applies potentials to the respective word lines WL via the word lines WLL and the vias 21.

In the circuit region, there are provided a write circuit which drives these driver circuits to write data in arbitrary memory cells, and a read circuit which drives these driver circuits to read data written in the arbitrary memory cells. In the circuit region where these circuits are provided, a device isolation film and a P-well and an N-well (not illustrated), and in these wells, elements, such as transistors, etc. are formed. The device 1 does not include an erase circuit which erases data written in the memory cells.

In the one time programmable semiconductor memory device 1 according to this embodiment, a bit line BL is selected to thereby select an X coordinate of the memory cells, an upper selection gate USG is selected to make an upper selection transistor conductive or non-conductive, whereby a Y coordinate of the memory cell is selected, and an electrode film WL is selected to thereby select a Z coordinate of the memory cell. Then, the potential of the selected silicon pillar SP is made lower than the potential of the selected electrode film WL to inject electrons from the silicon pillar SP into the chare storage film 26 of the selected memory cell by the FN tunneling, whereby information is stored. In the device 1 according to the present embodiment, which is a one time programmable memory device, data writing in the memory cells is made only once. The data once written in the respective memory cells are not erased and semi-permanently retained. When electrons are stored in a charge storage film 26, the threshold value of the transistor changes, whereby a sense current is flowed to the silicon pillar SP passing through the memory cell to thereby read information stored in the memory cell. The times of data reading are not limited, and the same data can be read plural times.

Next, the method of manufacturing the one time programmable semiconductor memory device according to this embodiment will be described.

FIGS. 4, 5 and 6 are cross-sectional views exemplifying the method of manufacturing the one time programmable semiconductor memory device according to this embodiment.

First, as illustrated in FIG. 4, an element isolation film (not illustrated) is formed in required positions in an upper layer portion of the silicon substrate 11. An impurity is injected into the memory array region to form the cell source CS in the upper layer portion of the silicon substrate 11. On the other hand, the P-well, the N-well, etc. are formed in the circuit region (not illustrated), and the source and drain of transistors forming the respective driver circuits are formed. Then, the gates of these transistors are formed.

Next, the insulating film 12 is deposited on the silicon substrate 11 and planarized. Then, non-crystalline silicon is deposited to form the lower selection gate LSG of conductive film, and the insulating film 13 to be the inter-layer film is formed thereon. Thus, the stacked body ML1 of the insulating film 12, the lower selection gate LSG and the insulating film 13 is formed on the silicon substrate 11.

Next, the through-hole 17a extended in the Z direction (stacking direction) and arriving at the cell source CS of the silicon substrate 11 is formed by lithograph and etching in the stacked body ML1. At this time, a plurality of the through-holes 17a are simultaneously formed, arranged in a matrix as viewed in the Z direction. The through-hole 17a is a hole for forming the lower selection transistor LST in a later process. At this time, the cell source CS of the silicon substrate 11 is temporarily exposed on the bottom surface of the through-hole 17a, but silicon oxide (not illustrated), such as natural oxide film or others Is unavoidably formed on this exposed surface.

Then, silicon nitride film is formed on the entire surface of the stacked body ML1. The silicon nitride film is formed also on the bottom surface and the side surface of the through-holes 17a in addition to the upper surface of the stacked body ML1. Then, the silicon nitride film formed on the upper surface of the stacked body ML1 and the bottom surface of the through-hole 17a is illustratively removed by RIE (Reactive Ion Etching),. At this time, the silicon nitride film remains to be the gate insulating film GD on the side surface of the through-hole 17a.

Next, wet etching with dilute hydrofluoric acid is illustratively made on the bottom surface of the through-hole 17a. The silicon oxide, such as natural oxide film, etc., is removed from the bottom surface of the through-hole 17a by this etching, and the cell source CS of the silicon substrate 11 is exposed on the bottom surface of the through-hole 17a. Next, non-crystalline silicon is buried in the through-hole 17a. Thus, the lower portion of the silicon pillar SP is formed in the through-hole 17a. Resultantly, the lower selection transistor LST is formed.

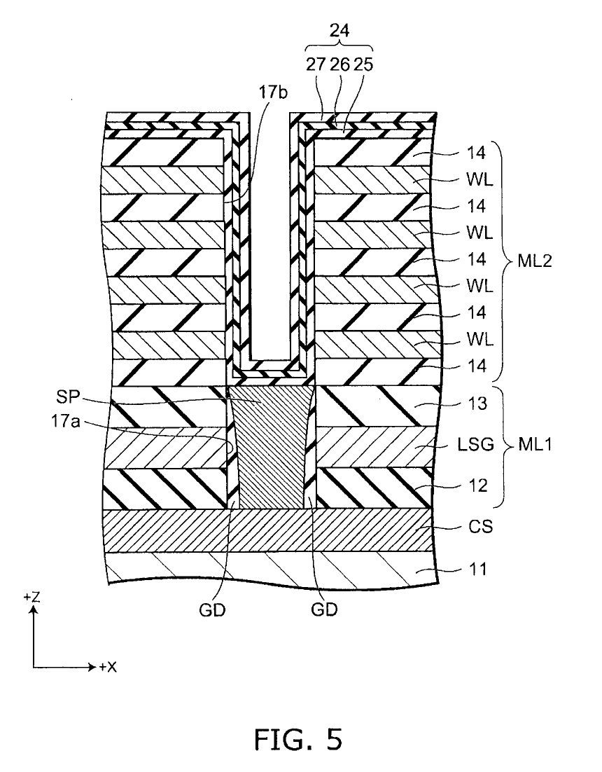

Next, as illustrated in FIG. 5, the inter-layer insulating film 14 and the electrode film WL are alternately stacked on the stacked body ML1 to form the stacked body ML2. Next, a photoresist film (not illustrated) is formed on the stacked body ML2 and patterned into a rectangle. By RIE with this photoresist film as the mask, the process of patterning one layer of the inter-layer insulating film 14 and one layer of the electrode film WL and the process of ashing the photoresist film to slim the external of the photoresist smaller are alternately repeated to process the ends of the stacked body ML2 in a step-shape.

Then, the through-holes 17b extended in the Z direction and arriving at the stacked body ML1 is formed by lithography and etching in the area of the stacked body ML2 immediately on the through-hole 17a. At this time, the through-hole 17a is communicated with the through-hole 17a. Then, the electrode-side insulating film 25 of silicon oxide, the charge storage film 26 of silicon nitride and the semiconductor-side insulating film 27 of silicon oxide are formed on the entire surface in the stated order to form the ONO film 24. The film thickness of the electrode-side insulating film 25 and the film thickness of the semiconductor-side insulating film 27 is respectively 4 nm or more, and the semiconductor-side insulating film 27 is formed thicker than the electrode-side insulating film 25. The ONO film 24 is formed on the upper surface of the stacked body ML2 and also on the bottom surface and the side surface of the through-hole 17b.

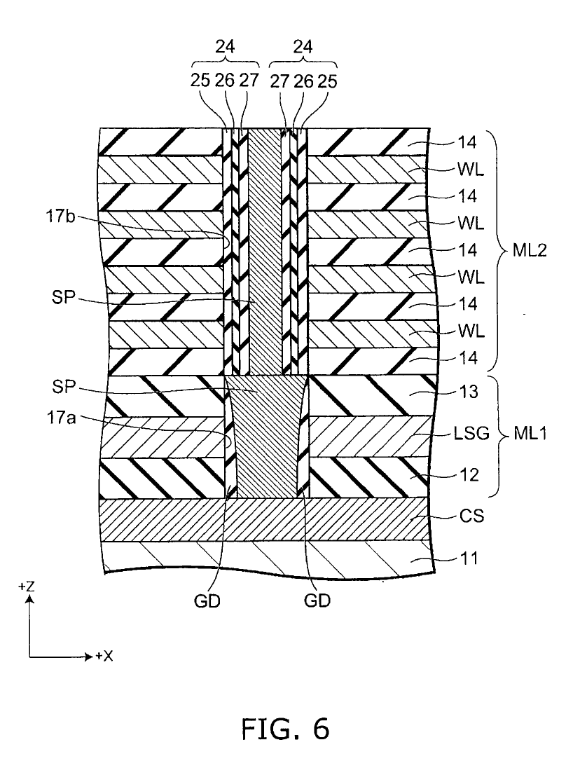

Next, as illustrated in FIG. 6, the ONO film 24 is removed from the upper surface of the stacked body ML2 and the bottom surface of the through-hole 17b. Thus, the ONO film 24 remains only on the side surface of the through-hole 17b. Then, non-crystalline silicon is buried inside the through-hole 17b to thereby form the middle portion of the silicon pillar SR Thus, transistors are formed at the intersections between the silicon pillar SP and the electrode films WL to serve as memory cells. At this time, the middle portion of the silicon pillar SP contacts the lower portion of the silicon pillar SR

Next, as illustrated in FIGS. 1 and 2, the stacked body ML3 is formed on the stacked body ML2 by the same process as the process of forming the stacked body ML1. The upper selection transistor UST is formed in the stacked body ML3. Next, the insulating film 18 is formed on the stacked body ML3. The via hole 18a is formed in the insulating film 18, and the vias 20, 21, 2 and the contact 23 are buried therein. Next, a metal film is formed on the entire surface and patterned to thereby form the bit lines BL, the upper selection gate lines USL, the word lines WL1, the lower selection gate lines LSL and the cell source lines CSL. Thus, the one time programmable semiconductor memory device 1 is manufactured.

Next, operation and effect of this embodiment will be described.

According to this embodiment, the memory cells can be three-dimensionally arranged in the stacked body ML2, whereby the integration of the memory cells can be improved. According to this embodiment, regardless of the number of stacked layers of the electrode film WL, the stacked body ML2 having the memory cells three-dimensionally arranged can be formed by forming once the through-holes 17b. Resultantly, even when the number of the stacked layer is increased, the time of the lithography does not increase, which can suppress the total manufacturing cost, and accordingly, the cost per 1 bit can be reduced. Thus, the one time programmable semiconductor memory device with high integration of the memory cells and low manufacturing cost can be realized.

In this embodiment, the film thickness of the electrode-side insulating film 25 and the semiconductor-side insulating film 27 sandwiching the charge storage film 26 is respectively 4 nm or more. Generally, when an insulating film has a film thickness of 4 nm or more, the direct tunneling does not take place, and when an electric field of a certain intensity is applied, FN tunneling alone takes place (see, e.g., Paragraph 0037 of the specification of JP-A 1997-306182). Accordingly, the electrons injected into the charge storage film 26 never pass through the electrode-side insulating film 25 to leak into the electrode films WL and passing through the semiconductor-side insulating film 27 to leak into the silicon pillars SP, due to the direct tunneling caused by the self-electric field. Resultantly, the one time programmable semiconductor memory device 1 according to this embodiment has good retention characteristics and can retain once-written data stably for a long period of time.

Furthermore, in this embodiment, the electrode-side insulating film 25 and the semiconductor-side insulating film 27 are formed of the same material, which can simplify the manufacturing process. Furthermore, the electrode-side insulating film 25 and the semiconductor-side insulating film 27 are formed of silicon oxide film, whose low electric field leak is small, hence the charge retention characteristics are good and the retention characteristics can be further improved.

Furthermore, in this embodiment, the electrode-side insulating film 25 is formed thinner than the semiconductor-side insulating film 27, whereby the diameter of the through-holes 17 can be small. This allows the plane structure of the device 1 to be downsized and can further improve the integration of the memory cells. The film thickness of the electrode-side insulating film 25 and the film thickness of the semiconductor-side insulating film 27 can be measured by, e.g., cutting the device 1 to expose the cross-sections of the electrode-side insulating film 25 and the semiconductor-side insulating film 27 and observing the cross-sections by a TEM (Transmission Electron Microscopy). In this case, the film thickness of the respective films is measured at plural portions, and the average values of the measured values may be adopted. This is the same in a second embodiment to be described later.

When the device of the same configuration as the device 1 is used as a repeatedly writable and erasable memory device, an erase circuit must be provided in the circuit region. This makes the circuit region of the device large. In this case, the operation of erasing data written in the memory cells is made by making the potential of the silicon pillars SP higher than the potential of the electrodes films WL, injecting holes from the silicon pillars SP into the charge storage film 26 and annihilating the electrons stored in the charge storage film 26. At this time, the electrode-side insulating film 25 must be sufficiently thicker than the charge storage film 26 so that while holes are being injected from the silicon pillars SP into the charge storage film 26, electrons are prevented from being reversely injected from the electrode films WL into the electron storage film 26. Oppositely, in the device according to this embodiment, where the electrode-side insulating film 25 is thinner than the semiconductor-side insulating film 27, such erase operation cannot be made. However, the device 1 according to this embodiment is a one time programmable memory device and does not require the erase operation, therefore no problem takes place.

Generally, when the electrode-side insulating film 25 is thin, the write operation of data might have troubles. That is, there is a possibility that holes might be injected from the electrode films WL into the charge storage film 26 when electrons are injected from the silicon pillars SP into the charge storage film 26. However, in this embodiment, because of the cylindrical shape of the silicon pillars SP, the radius of curvature of the electrode-side insulating film 25 outer positioned is larger than the radius of curvature of the semiconductor-side insulating film 27 inner positioned, and its curve is smooth. Accordingly, the electric field to be applied to the electrode-side insulating film 25 is more relaxed than the electric field to be applied to the semiconductor-side insulating film 27, and the write operation has no problem.

Next, variations of this embodiment will be described.

First, a first variation of this embodiment will be described.

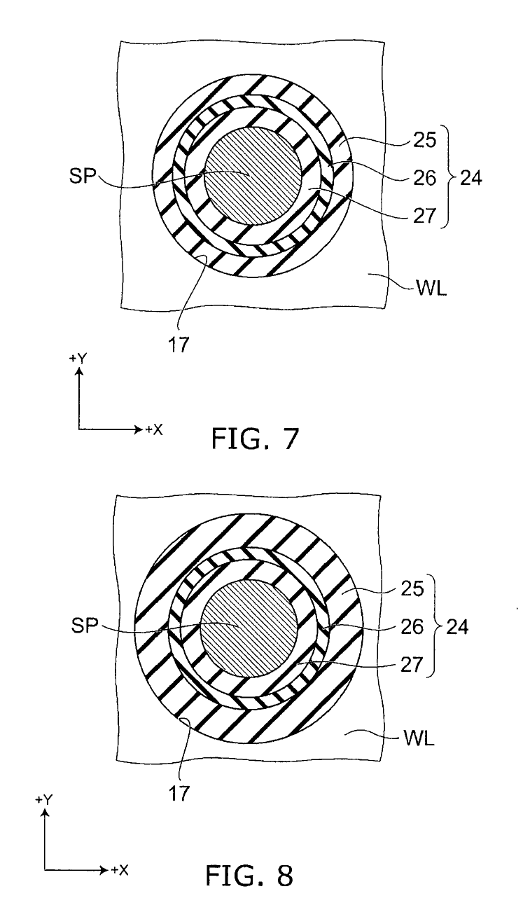

FIG. 7 is a partial cross-sectional view exemplifying the inside of the through-hole of the one time programmable semiconductor memory device according to this variation.

As illustrated in FIG. 7, in the one time programmable semiconductor device according to this variation, the film thickness of the electrode-side insulating film 25 is equal to the film thickness of the semiconductor-side insulating film 27. In comparison with the first embodiment described above, although the diameter of the through-holes 17 is a little larger than the diameter of the through-holes 17 of the first embodiment, this makes the write operation more stable. The configuration, the manufacturing method and the operation and effect of this variation other than those described above are the same as those of the first embodiment described above.

Next, a second variation of this embodiment will be described.

FIG. 8 is a partial cross-sectional view exemplifying the inside of the through-holes of the one time programmable semiconductor device according to this variation.

As illustrated in FIG. 8, in the one time programmable semiconductor memory device according to this variation, the film thickness of the electrode-side insulating film 25 is larger than the film thickness of the semiconductor-side insulating film 27. In comparison with the first variation described above, although the diameter of the through-holes 17 is further larger, the write operation can be more stable. The shape of the silicon pillars is not limited to a cylinder, thereby the degree of freedom in design increases. The configuration, the manufacturing method and the operation and effect of this variation other than those described above are the same as those of the first embodiment described above.

Next, a second embodiment of this invention will be described.

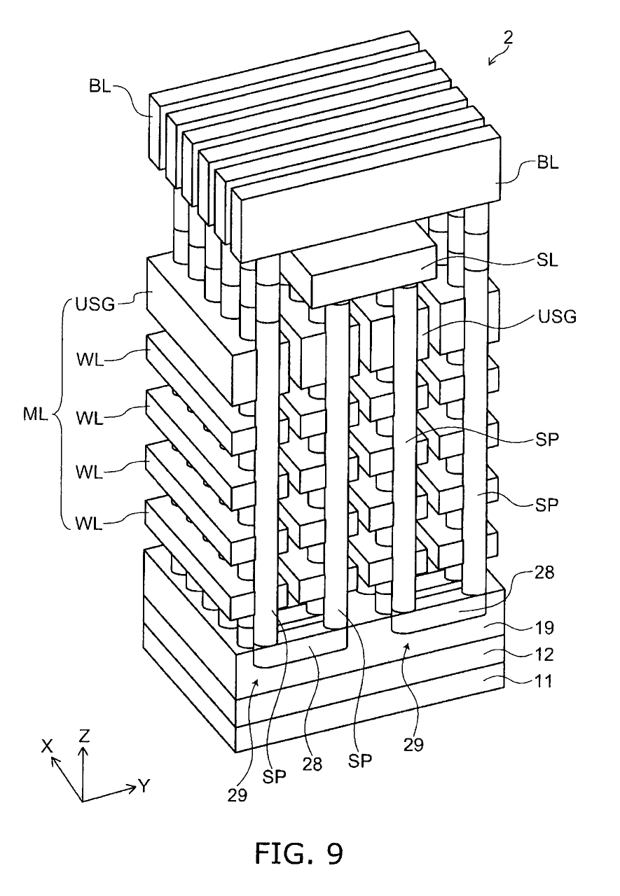

FIG. 9 is a perspective view exemplifying the one time programmable semiconductor memory device according to the present embodiment.

In the fist embodiment and its variations described above, the bit lines BL are provided above the silicon pillars SP, the cell source CS is provided under the silicon pillars SP, and the silicon pillars SP is I-shaped. In this embodiment, however, U-shaped pillars are illustratively provided.

As illustrated in FIG. 9, in the one time programmable semiconductor memory device 2 (hereinafter called also “the device 2”) according to this embodiment, a pair of silicon pillars SP adjacent to each other in the Y direction are connected by a connection member 28, forming one U-shaped pillar 29. The connection member 28 is formed integrally of the same semiconductor material as the silicon pillars SP. The connection members 28 are buried in a back gate electrode film 19 provided on the insulating film 12. Furthermore, an electrode-side insulating film 25, a charge storage film 26 and a semiconductor-side insulating film 27 are provided sequentially from the side of the back gate electrode 19 between the connection members 28 and the back gate electrode 19. A source line SL extended in the X direction is provided above the silicon pillars SP, e.g., between the upper selection gates USG and bit lines BL. The U-shaped silicon member 29 has one end connected to the source line SL and the other end connected to a bit line BL. Furthermore, the electrode films WL are divided for every column of the silicon pillars SP arranged in the X direction.

The device 2 can be manufactured by forming U-shaped through-holes in a stacked body ML, forming an ONO film 24 on the inside surfaces of the through-holes and them burying silicon in the through-holes. This process, which does not require the removal of the ONO film 24 from the bottom surfaces of the through-holes, can lower the difficulty of the process in comparison with the first embodiment described above. The configuration, the manufacturing method and the operation and effect of this embodiment other than those described above are the same as those of the first embodiment described above. That is, in the device 2 as well, the electrode-side insulating film 25 and the semiconductor-side insulating film 27 are formed of silicon oxide, and the film thickness is respectively 4 nm or more.

Next, a third embodiment of this invention will be described.

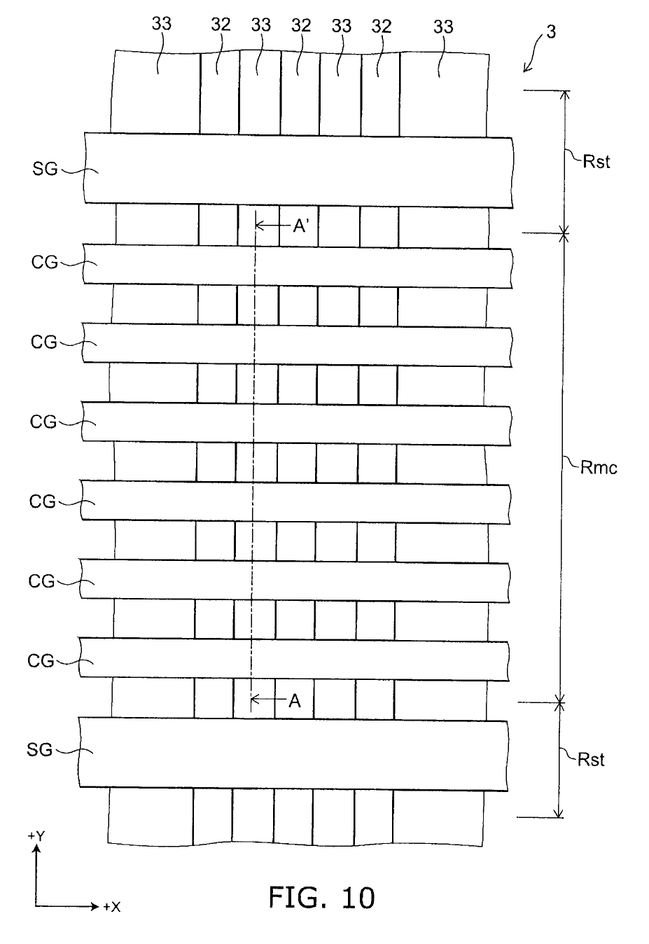

FIG. 10 is a plan view exemplifying the one time programmable semiconductor memory device according to this embodiment.

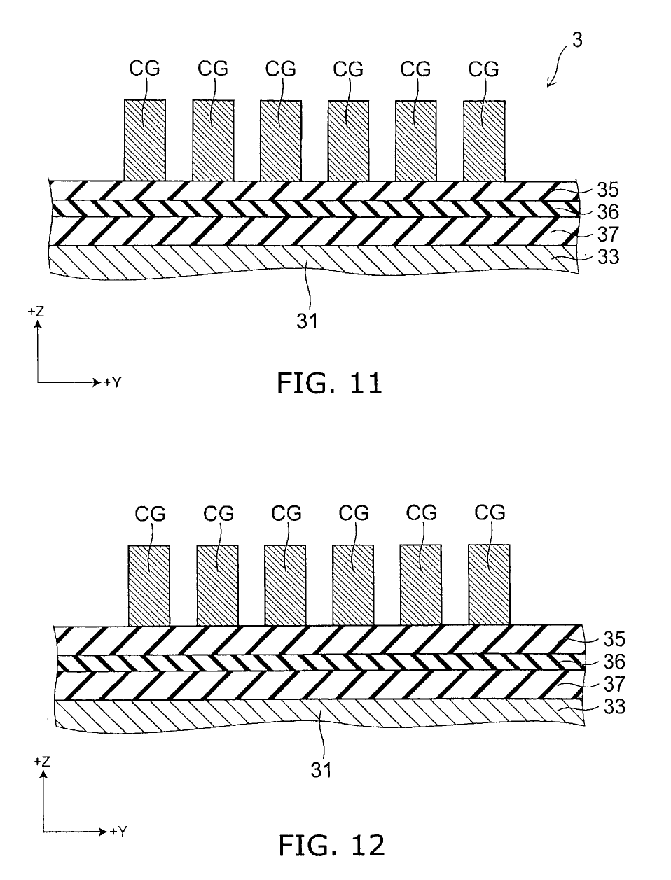

FIG. 11 is a cross-sectional view along the A-A′ line in FIG. 10.

As illustrated in FIGS. 10 and 11, the one time programmable semiconductor memory device according to the present embodiment (hereinafter simply called also “the device 3”) is a plane memory device. In the device 3, a silicon substrate 31 is provided.

The device 3 is provided with a memory array region where a plurality of memory cells are provided and a peripheral region where peripheral circuits for driving the memory array region, In the circuit region, there are provided a driver circuit for respectively supplying potentials of the respective lines to the memory array region, a write circuit for driving the driver circuits to write data in arbitrary memory cells, and a read circuit for reading data from arbitrary memory cells. The device 3 is a one time programmable memory device, and hence does not include an erase circuit for erasing data written the memory cells.

A memory cell region Rmc is configured in the memory cell array region. A pair of selection transistor regions Rst are configured in the regions sandwiching the memory cell region Rmc. Hereinafter, for the convenience of the description, of the directions parallel with the upper surface of the silicon substrate 31, the direction of the layout of the selection transistor region Rst, the memory cell region Rmc and the selection transistor region Rst is the “Y direction”, the direction orthogonal to the Y direction is the “X direction”. The direction perpendicular to the upper surface of the silicon substrate 31 is the “Z direction”.

In an upper layer portion of a silicon substrate 31, a plurality of element isolation insulators 32 are formed by STI (Shallow Trench Isolation). The element isolation insulators 32 are formed by burying silicon oxide (SiO₂) in the trenches, have a stripe-shape extended in the Y direction and divide the upper layer portion of the silicon substrate 31 into a plurality of semiconductor portions 33. The semiconductor portions 33 function as active areas (AA) of memory strings which will be described later. The respective element isolation insulator 32 and the semiconductor portions 33 are extended from one Rst of the selection transistor region Rst to the other selection transistor Rst, passing through the memory cell region Rmc. That is, the element isolation insulators 32 and the semiconductor portions 33 have both ends in the Y direction positioned in the selection transistor regions Rst and the middle portions position in the memory cell region Rmc.

A semiconductor-side insulating film 37 is provided in the areas immediately on the semiconductor portions 33 in the memory cell region Rmc. The semiconductor-side insulating film 37 causes no direct tunneling and is usually insulating. When a prescribed voltage in the range of a drive voltage of the device 3 is applied, the semiconductor-side Insulating film 37 generates direct tunneling and flows a tunnel current. The semiconductor-side insulating film 37 has a film thickness causing no direct tunneling, i.e., of 4 nm or more and which generates FN tunneling when a prescribed voltage is applied.

A charge storage film 36 is provided on the semiconductor-side insulating film 37. The chare storage film 36 is a film which can retain charges and has, e.g., trap sites of electrons and is formed of, e.g., silicon nitride (SIN). Furthermore, an electrode-side insulating film 35 is provided on the charge storage film 36. The electrode-side insulating film 35 has a film thickness causing no direct tunneling and is specifically 4 nm or more. The semiconductor-side insulating film 37 and the electrode-side insulating film 35 are formed of the same material, e.g., silicon oxide (SiO₂).

A plurality of linear control gate electrodes CG extended in the X direction are provided on the electrode-side insulating film 35. The control gate electrodes CG are formed of, e.g., a metal. On the other hand, gate insulating films (not illustrated) of, e.g., silicon oxide are formed in the areas very on the semiconductor portions 33 in the selection transistor regions Rst. Line-shaped selection gate electrodes SG extended in the X direction are provided on the gate insulating films. The selection gate electrodes SG are formed of, e.g., a metal

In the device 3, an inter-layer insulating film (not illustrated) is provided so as to bury the semiconductor-side insulating film 37, the charge storage film 36, the electrode-side insulating film 35, the control gate electrodes CG, the gate insulating film (not illustrated) and the selection gate electrodes SG. Bit lines (not illustrated) extended in the Y direction are provided for the every semiconductor portion 33 on the inter-layer insulating film. The respective bit lines are connected to the respective semiconductor portions 33 via contacts (not illustrated) formed in the inter-layer insulating film.

In the device 3 according to this embodiment, memory cells of MONOS transistors are formed at the every nearest point between the respective semiconductor portions 33 functioning as active areas (AA) and the respective control gates CG functioning as the word lines. The plurality of memory cells arranged in the Y direction and having the semiconductor portion 33 in common form a memory string. Selection transistors are formed at the every nearest point between the respective gate electrodes SG and the respective semiconductor portions 33. The selection transistors are connected to both ends of the memory strings. The plurality of control gates CG extended in the X direction cross the plurality of the semiconductor portions 33 are extended in the Y direction. Thus, a plurality of the memory cells are arranged in a matrix in the memory array region. The write method and the read method of data for the respective memory cells are the same as those of the first embodiment.

Next, operation and effect of this embodiment will be described.

According to this embodiment, the memory cells are formed of MONOS transistors with simple configuration, and are two-dimensionally arranged, whereby while the manufacturing cost being suppressed, the integration of the memory cells can be improved. Thus, a one time programmable semiconductor memory device of high integration of the memory cells and low manufacturing cost can be realized.

In this embodiment, the film thickness of the electrode-side insulating film 35 and the semiconductor-side insulating film 37 sandwiching the charge storage film 36 is respectively 4 nm or more. This prevents the electrons injected into the charge storage film 36 from passing through the electrode-side insulating film 35 by the direct tunneling caused by the self electric fields and leaking into the control gate electrodes CG or passing through the semiconductor-side insulating film 37 and leaking into the semiconductor portions 33. Resultantly, data once written can be retained long stably.

Furthermore, in this embodiment, the electrode-side insulating film 36 is formed thinner than the semiconductor-side insulating film 37, which makes the manufacturing costs further low.

Furthermore, in this embodiment, the electrode-side insulating film 35 and the semiconductor-side insulating film 37 are formed of the same material, which can simplify the manufacturing process. Furthermore, the electrode-side insulating film 35 and the semiconductor-side insulating film 37 are formed of silicon oxide film, whose low electric field leak is low, hence the charge retention characteristic is good, and the retention characteristic can be further improved.

When the device of the same configuration as the device 3 is used as a repeatedly writable and erasable memory device, an ease circuit must be provided in the circuit region. This makes the circuit region of the device large. In this case, the erase of data written in the memory cells is made by making the potential of the semiconductor portions 33 higher than the potential of the control gate electrodes CG, injecting holes from the semiconductor portions 33 into the charge storage film 36 and annihilating the electrons stored in the charge storage film 36. At this time, in the plane device 3, the electric field relaxation effect due to the different radii of curvatures cannot be provided, as can be in the device 1 according to the first embodiment described above, and when the dielectric constant of the electrode-side insulating film 35 and the dielectric constant of the semiconductor-side insulating film 37 are equal to each other, the intensity of the electric field to be applied to the electrode-side insulating film 35 and the intensity of the electric field to be applied to the semiconductor-side insulating film 37 become equal to each other. Accordingly, when holes are injected from the semiconductor portions 33 into the charge storage film 36, electrons are reversely injected from the control gate electrodes CG into the charge storage film 36, and the erase operation cannot be carried out.

In such device, to make the erase operation, while holes are being injected from the semiconductor portions 33 into the charge storage film 36, electrons must be prohibited from being injected from the control gate electrodes CG reversely into the charge storage film 36. To this end, the following methods are considered.

As a first method, in order to flow current only to the semiconductor-side insulating film, although the electric field to be applied are the same, it is considered to make the semiconductor-side insulating film as thin as the direct tunneling takes place. That is, the film thickness of the semiconductor-side insulating film is made 4 nm or less. However, in this case, the electrons injected into the charge storage film tend to leak through the semiconductor-side insulating film, and retention characteristic is deteriorated. Accordingly, it is difficult to stably retain data long.

As a second method, to relax the electric field to be applied to the electrode-side insulating film, it is considered to form the electrode-side insulating film of a material having a higher dielectric constant than the semiconductor-side insulating film. For example, when the semiconductor-side insulating film is formed of silicon oxide (SiO₂), the electrode-side insulating film is formed of alumina (Al₂O₃). However, in this case, the low electric field leak current of the electrode-side insulating film becomes large, and the retention characteristic is also deteriorated.

Thus, it is impossible to use a device of the same configuration as the device 3 according to this embodiment as a repeatedly writable and erasable memory device. However, the device 3 according to this embodiment is a one time programmable (OTP) memory device and does not require erase operation, hence no problem takes place.

Next, variations of this embodiment will be described.

First, a first variation of this embodiment will be described.

FIG. 12 is a cross-sectional view exemplifying the one time programmable semiconductor memory device according to this variation.

As illustrated in FIG. 12, in the one time programmable semiconductor memory device according to this variation, the film thickness of the electrode-side insulating film 35 and the film thickness of the semiconductor-side insulating film 37 are equal to each other. This stabilizes the write operation more in comparison with the third embodiment described above, although the film formation time for the electrode-side insulating film 35 becomes longer. The configuration and the manufacturing method and operation and effect of this variation other than those described above are the same as those of the third embodiment.

Next, a second variation of this embodiment will be described.

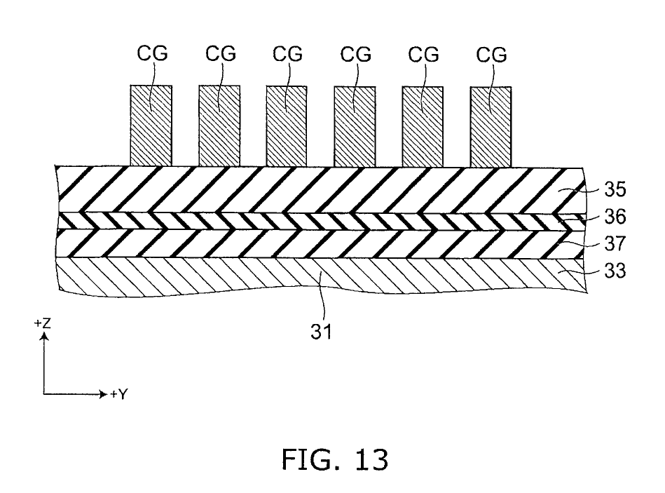

FIG. 13 is a cross-sectional view exemplifying the one time programmable semiconductor memory device according to this variation.

As illustrated n FIG. 13, in the one time programmable semiconductor memory device according to this variation, the electrode-side insulating film 35 is thicker than the semiconductor-side insulating film 37. This makes the film formation time for the electrode-side insulating film 35 longer in comparison with that of the first variation of the third embodiment, but can stabilize the write operation further. The configuration, the manufacturing method and operation and effect of this variation other than those described above are the same as those of the third embodiment describe above.

This invention has been so far described with reference to embodiments and their variations but is not limited to the embodiments and the variations. The respective embodiments and variations described above to which those skilled in the art suitably add or delete constituent elements or make design changes or which those skilled in the art add or delete process or make condition changes are covered by this invention as long as they are in the spirits of this invention.

1. A semiconductor memory device comprising:
a stacked body formed of a plurality of inter-layer insulating films and a plurality of electrode films alternately stacked and having a through-hole formed in the stacking direction;
an electrode-side Insulating film of a film thickness of 4 nm or more provided on an inner surface of the through-hole;
a charge storage film provided on the electrode-side insulating film;
a semiconductor-side insulating film of a film thickness of 4 nm or more provided on the charge storage film; and
a semiconductor pillar buried in the through-hole.

2. The device according to claim 1, wherein the electrode-side insulating film and the semiconductor-side insulating film are formed of identical material.

3. The device according to claim 2, wherein
the electrode-side insulating film and the semiconductor-side insulating film are formed of silicon oxide.

4. The device according to claim 1, wherein
the film thickness of the electrode-side insulating film is smaller than the film thickness of the semiconductor-side insulating film.

5. The device according to claim 1, wherein
the device is one time programmable.

6. A semiconductor memory device comprising:
a semiconductor substrate;
a semiconductor-side insulating film of a film thickness of 4 nm or more provided on the semiconductor substrate;
a charge storage film provided on the semiconductor-side insulating film;
an electrode-side insulating film of a film thickness of 4 nm or more provided on the charge storage film; and
an electrode provided on the electrode-side insulating film,
the semiconductor-side insulating film and the electrode-side insulating film being formed of identical material.

7. The device according to claim 6, wherein
the electrode-side insulating film and the semiconductor-side insulating film are formed of silicon oxide.

8. The device according to claim 6, wherein
the film thickness of the electrode-side insulating film is smaller than the film thickness of the semiconductor-side insulating film.

9. The device according to claim 6, wherein
the device is one time programmable.
